(19) United States
(12) Patent Application Publication
(10) Pub. No.: US 2026/0113851 A1
(43) Pub. Date: Apr. 23, 2026

(54) PCB STENCIL PRINTING WITH SHRINKAGE COMPENSATION

(71) Applicant: INTERNATIONAL BUSINESS MACHINES CORPORATION, Armonk, NY (US)

(72) Inventors: WeiFeng Zhang, Shenzhen (CN); Jiayu Zheng, Foshan (CN); YanLong Hou, Shenzhen (CN); Lin Zhao, Shenzhen (CN)

(21) Appl. No.: 18/918,581

(22) Filed: Oct. 17, 2024

(51) Int. Cl. H05K 3/00; H05K 3/12

(52) U.S. Cl. CPC H05K 3/0008; H05K 3/1225; H05K 2203/0195; H05K 2203/163; H05K 2203/168

(57) ABSTRACT

A method for adjusting a solder paste stencil includes preloading a solder paste stencil in contact with a printed circuit board. Processing warpage is measured between the solder paste stencil and the printed circuit board to determine a dimensional offset strain due to the warpage. A stress to be applied to the stencil is determined by accessing a neural network to output the stress based on the dimensional offset strain. The stress is applied to the stencil to compensate for the warpage.

### BACKGROUND

The present invention generally relates to printed circuit board processing and, more particularly, to systems and methods for compensation of stencil and printed circuit board mismatches in printed circuit board fabrication.

A Printed Circuit Board (PCB) stencil is typically a thin sheet of stainless steel with openings that are generally laser-cut therein. The stencil is used for the application of solder paste to a circuit board to attach surface-mounted components. PCB stencils are utilized for solder paste coating over specific locations on the circuit board, which allows these components to be placed accurately in position and aligned. The stencil delivers an appropriate amount of solder paste to surface mount technology (SMT) pads to ensure that the joints maintain mechanical strength and electrical connectivity.

PCB stencils are broadly manufactured by incorporating stainless steel foil-based sheet metal plates with cutouts for surface mount components. The stencil is placed on the circuit board and perfectly aligned using registration points called fiducial marks. After alignment, the solder-paste is applied using a metal squeegee. Using the right PCB stencil when applying solder paste can speed up the PCB assembly process.

For PCB assembly (PCBA) manufacturing processes, it is very difficult to ensure PCB size tolerances with shrinkage or expansion of the components. Compensation for shrinkage is extremely difficult as it is challenging to predict shrinkage across an entire PCB. The shrinkage or expansion of the components (e.g., solder paste shift) can vary with different designs, different material suppliers and different PCB designs. As such, improper compensation for PCBs and PCB stencils can cause a high defect rate. Therefore, a need exists for compensating for solder paste shift.

### SUMMARY

In accordance with an embodiment of the present invention, a method for adjusting a solder paste stencil includes preloading a solder paste stencil in contact with a printed circuit board. Processing warpage is measured between the solder paste stencil and the printed circuit board to determine a dimensional offset strain due to the warpage. A stress to be applied to the stencil is determined by accessing a neural network to output the stress based on the dimensional offset strain. The stress is applied to the stencil to compensate for the warpage.

In other embodiments, dimensional offsets can be reevaluated to reapply an updated stress in a closed feedback loop. Measuring processing warpage can include inspecting dimensional offset between the solder paste stencil and the printed circuit board using an automated optical inspection tool. Measuring processing warpage between the solder paste stencil and the printed circuit board can also include employing fiducial markers to estimate strain across the printed circuit board. Determining the stress to be applied to the solder paste stencil can include inferencing the neural network to output an optimized stress parameter based upon historical defect data. The inferencing of the neural network can include using a largest deformation in a worst use case and a strain range to determine the stress to be applied to the solder paste stencil. The stress can be applied by tensioning a wire mesh supporting the solder paste stencil using one or more net haulers. A same stencil can be used for a plurality of different printed circuit board substrates by adjusting a size of the solder paste stencil.

In accordance with another embodiment of the present invention, a system for adjusting a solder paste stencil includes a hardware processor and a memory that stores a computer program which, when executed by the hardware processor causes the hardware processor to apply a preload to a solder paste stencil in contact with a printed circuit board and in response to processing warpage measurements between the solder paste stencil and the printed circuit board, determine a dimensional offset strain due to the warpage. A stress to be applied to the stencil is determined by accessing a neural network to output the stress based on the dimensional offset strain, and signals are generated to apply the stress to the stencil to compensate for the warpage.

In other embodiments, the computer program can cause the hardware processor to reevaluate dimensional offsets to reapply an updated stress in a closed feedback loop. The computer program can cause the hardware processor to determine the dimensional offset strain due to the processing warpage in accordance with measurements of an automated optical inspection tool. The computer program can cause the hardware processor to estimate strain across the printed circuit board using fiducial markers. The computer program can cause the hardware processor to determine the stress to be applied to the solder paste stencil by inferencing the neural network to output an optimized stress parameter based upon historical defect data. The computer program can cause the hardware processor to determine the stress to be applied to the solder paste stencil by inferencing the neural network with a largest deformation in a worst use case and a strain range to determine the stress to be applied to the solder paste stencil. The computer program can cause the hardware processor to apply the stress to the solder paste stencil by tensioning a wire mesh supporting the solder paste stencil using one or more net haulers. A same stencil can be employed for a plurality of different printed circuit board substrates by adjusting a size of the solder paste stencil.

In accordance with another embodiment of the present invention, a computer program product for adjusting a solder paste stencil includes a computer readable storage medium having program instructions embodied therewith. The program instructions are executable by a hardware processor to cause the hardware processor to apply a preload to a solder paste stencil in contact with a printed circuit board; in response to processing warpage measurements between the solder paste stencil and the printed circuit board, determine a dimensional offset strain due to processing warpage; determine a stress to be applied to the solder paste stencil by accessing a neural network to output the stress based on the dimensional offset strain; and generate signals to apply the stress to the solder paste stencil to compensate for the processing warpage.

In other embodiments, the program instructions can cause the hardware processor to reevaluate dimensional offsets to reapply an updated stress in a closed feedback loop. The computer program product can cause the hardware processor to determine the stress to be applied to the solder paste stencil by inferencing the neural network to output an optimized stress parameter based upon historical defect data. The computer program product can cause the hardware processor to determine the stress to be applied to the solder paste stencil by inferencing the neural network with a largest deformation in a worst use case and a strain range to determine the stress to be applied to the solder paste stencil.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a schematic diagram showing a solder paste stencil preloaded in a frame using wire mesh and net haulers, in accordance with an embodiment of the present invention;

FIG. 2 is a block/flow diagram showing a system for compensating for processing warpage in a solder paste stencil, in accordance with an embodiment of the present invention;

FIG. 3 is a diagram showing measurement data for a printed wiring board and including a magnified view of a worst case deformation, in accordance with an embodiment of the present invention;

FIG. 4 is a graph showing a stress-strain curve showing compensating for warpage (shrinkage or expansion) of a stencil, in accordance with an embodiment of the present invention;

FIG. 5 is a block/flow diagram showing an illustrative process for populating a printed wiring board using a neural network in a closed feedback loop, in accordance with an embodiment of the present invention;

FIG. 6 is a schematic diagram showing usage of fiducial marker recognition for estimating a strain, in accordance with an embodiment of the present invention;

FIG. 7 is a diagram showing a neural network for an artificial intelligence (AI) model for compensation of processing warpage, in accordance with an embodiment of the present invention;

FIG. 8 is a block/flow diagram showing a computer system for compensating for processing warpage in a solder paste stencil, in accordance with an embodiment of the present invention; and

FIG. 9 is a flow diagram showing methods for compensating for processing warpage in a solder paste stencil, in accordance with an embodiment of the present invention.

### DETAILED DESCRIPTION

In accordance with embodiments of the present invention, system and methods are provided that compensate for solder paste shift in PCB fabrication. Paste mask layers or stencils are employed in surface mount device (SMD) assembly applications. SMD assembly includes soldering processes where SMD pads are coated with a conductive paste (e.g., including tin). The stencil is placed on a circuit board and aligned therewith. Then, a paste is applied on the stencil with the paste passing through openings in the stencil. Excess paste is removed with a blade, and then the stencil is removed. Solder pads covered with paste are then employed to attach components to the PCB with the solder paste (either by hand or with a pick and place machine). The SMD assembly is completed with a reflow soldering machine. The stencil hole sizes are usually smaller than an actual weld pad on the PCB. A paste mask layer or stencil can also be split into a top stencil and a bottom stencil for processing a top and a bottom side of the PCB.

In accordance with embodiments of the present invention, solder printing performance is improved by accounting for thermal expansion and shrinkage in a PCB during processing. After solder printing and pick and place mounting of components and reflow soldering on a first side of the PCB, the PCB will be warped or subject to shrinkage or expansion due to PCB laminate characteristics. An amount of PCB shrinkage (e.g., ε_{pcb}) could be measured either by fiducial mark recognition from a solder printing machine or any dimensional measurement techniques (e.g., coordinate measuring machine (CMM), etc.). While the fiducial mark recognition can provide some compensation for the dimensional fluctuations of the PCB, it is limited and cannot compensate for larger PCB shrinkage scenarios.

A solder printing system in accordance with embodiments of the present invention is designed with an adaptive deformable printing stencil to match PCB deformation in multiple solder printing steps and processes during the PCB assembly process. During a first solder printing (before the PCB goes through a first reflow), the printing stencil is pre-stressed to generate and maintain overall stencil dimensions including a pad layout and position to match original PCB dimensions and pad design. After the first reflow and components assembly is completed, the PCB deforms, which can lead to mismatches between the stencil and the deformed PCB.

To adopt the deformed PCB and compensate for offsets of pads on the PCB during a second reflow and component assembly, the stencil is deformed as well to maintain alignment with the PCB and its pads. The stencil can be loaded to produce elastic deformation by changing a loaded stress on the stencil to provide an adjusted stencil. Local adjustments can be made in the stencil to further fine-tune the adjusted stencil. A second round assembly can be performed on the PCB based on the fine-tuned stencil. In this way, stencil features can align better with PCB features especially after processes that expand or shrink the PCB.

Accurate calculations and analysis are carried out to achieve a match between the adjusted stencil and deformed PCB. The amount of PCB deformation (ε_{pcb}) can be measured by a dimensional measurement tool (e.g., CMM) from the solder printing system and analyzed by an artificial intelligence (AI) module or system. The AI module provides an optimal parameter and solution as input for the solder printing system to adjust the printing stencil. After all assembly processes are completed, the solder printing system restores parameters to initial values, and the printing stencil is recovered to initial conditions and prepared for a next production process.

The printing stencil can be elastically deformed (a temporary deformation of a material's shape) and self-reversed after removing an applied load within the elastic limit of the stencil. Elastic deformation of metals is commonly seen at low strains, and their elastic behavior is generally linear.

In an embodiment, specific materials are employed to design the stencil. The stencil can extend to an expected size to match different PCBs. PCBs can be different based on the materials, vendors, specifications, etc. A mechanical design of the stencil can be specifically printed for the adjustable stencil. An additive manufacturing process can be employed to vary the materials of the stencil, as needed. A closed loop based AI model can compute a warpage measurement. The AI model can provide accurate calculations, analysis and printing parameters.

The solutions in accordance with the present embodiments that address the PCB shrinkage and expansion issue can save on repair, scrap and disposition costs. The present embodiments can eliminate the need for multiple special stencils to match each vendor's PCB, this can save stencil cost and reduce new stencil lead time. The present embodiments can easily be integrated into existing stencil design and manufacturing processes. Quality closed loop management can ensure real time monitoring of dimensions. The AI model can auto adjust the stencil with program parameters and can accordingly adjust solder paste volume, etc.

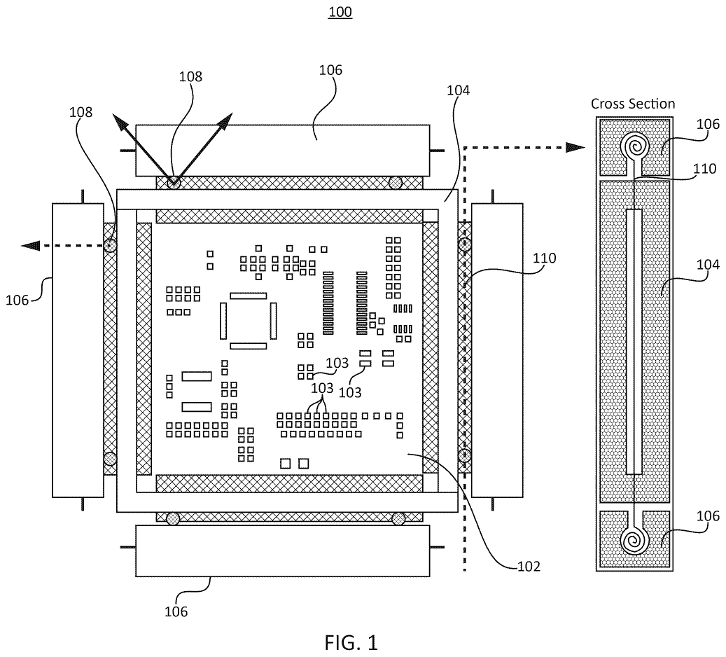

Referring now to the drawings in which like-numerals represent the same or similar elements and initially to FIG. 1, a system 100 for solder printing using a printing stencil, or simply a stencil, 102 is shown. The stencil 102 is held to a woven wire mesh 110. The wire mesh 110 can include an inorganic fiber mesh, stainless steel wire mesh, polymer polyester mesh or other material mesh. A frame 104 or screen frame permits the wire mesh 110 to pass therethrough and provides support and stability to the arrangement of the wire mesh 110. Net haulers 106 or net reeling units are employed to tension the wire mesh 110 at each of four sides of the wire mesh 110. Tow points 108 provide connection points to make adjustments to the wire mesh 110.

Frames 104 can be movable or fixed. Movable frames can attach a steel plate directly to the frame, and a template frame can be used repeatedly. The frame 104 is a fixed frame that attaches to the wire mesh 110 with an adhesive. The frame 104 can be tensioned to between about 35 and 42 N/cm². The stencil 102 can include a copper plate, stainless steel plate, nickel alloy, polyester, etc.

The stencil 102 includes openings 103 that can be precisely laser-cut. The openings 103 correspond to pad locations of a PCB (not shown). Solder paste is applied to the stencil 102 and passed into the openings 103. When the stencil 102 is removed the solder paste remains over the pads of the PCB. Components are then placed and the solder paste is reflowed using a radiant heat source or other source.

The reflow heat causes expansion of the PCB and the stencil 102, but at different rates due to geometric and material property differences. A center area of the PCB has no shift issues, but peripheral areas (e.g., the four corners) of the PCB could have a large shift, e.g., 0.201 mm or 39% of chip 0402 pads. This offset difference is even more pronounced, when an opposite side of the PCB is also to be solder pasted. This difference in expansion results in misalignments. High tombstone defects can be found by automated optical inspection (AOI) devices after reflow soldering due to the solder paste shift issue and PCB shrinkage, which causes the solder paste shift.

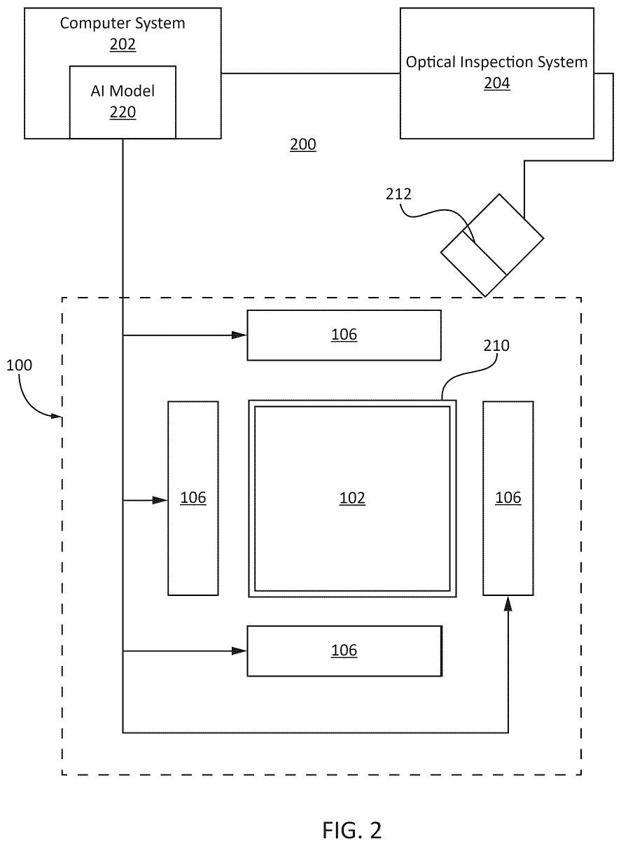

Referring to FIG. 2, a system 200 for aligning a stencil is shown in accordance with embodiments of the present invention. The system 100 includes feedback control for tensioning the wire mesh 110 using the net haulers 106 and tow points (108, FIG. 1). An inspection system 204, such as an AOI, with a camera 212 or other sensors, measures alignment with a PCB 210 (shown as an outline under the stencil 102). A computer system 202 or systems with an artificial intelligence (AI) model 220 can be employed to take the measurement of the inspection system 204 and convert observed misalignments and strains and convert them to tensioning values for the net haulers 106 and tow points 108.

The computer system 202 sends control signals to the net haulers 106 (and/or the tow points 108). That can control servos or actuators that control tensioning of the wire meshes 110.

The tensioning values can be adjusted over time and in accordance with changes during the solder printing process.

In an example embodiment, an adjustable strain range can be determined that applies and maintains alignment with specifications despite differences in expansion or contraction due to thermal changes between the stencil 102 and the PCB 210. This strain range can be calculated by the AI model 220 using the image measurements from the inspection system 204. The PCB specification strain limit can be based on PCB dimensional tolerances.

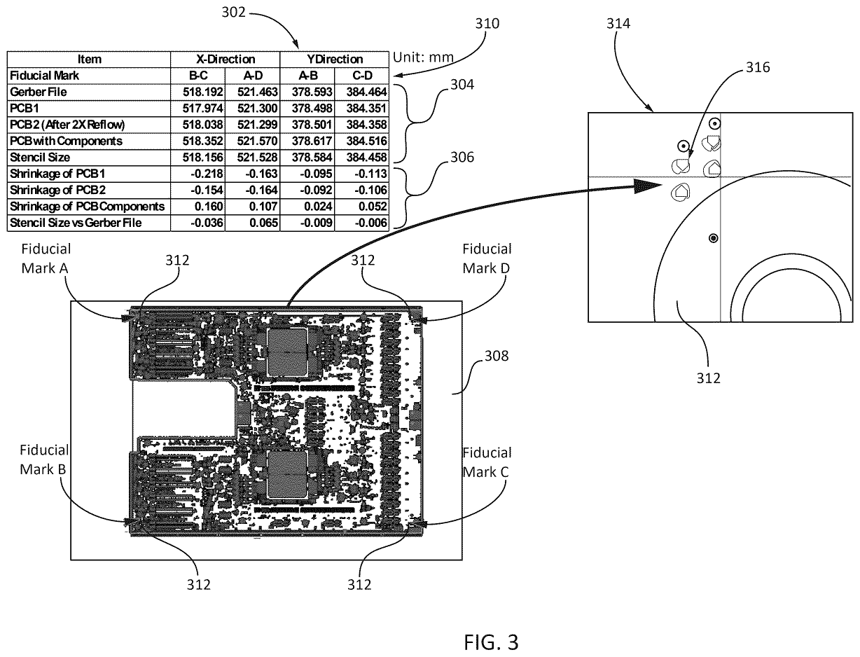

Referring to FIG. 3, in an example, a table 302 shows dimensional measurements 304 for a PCB 308 from a dimensional inspection. The dimensional measurements 304 are taken between fiducial markers 312 (A, B, C and D). Which fiducial markers 312 are considered in measurements is indicated in row 310. A PCB dimensional specification tolerance can be, e.g., +/−0.13 mm with actual dimensions of the PCB 308 around 520 mm by 380 mm. In this example, the specification strain limit regarding PCB deformation in the X direction is +/−0.025% (0.13/520) and +/−0.034% (0.13/380) in the Y direction. A largest deformation in a use case (worst case scenario) can be considered.

The worst scenario from the table is shrinkage of the PCB 308 by −0.042% (−0.218/518, B to C) and −0.031% (−0.163/521, A to D) in the X direction, which caused 39.648% offset in the X direction between printed solders and bonding pads for an 0402 package component 316 (e.g., pad dimensions =1 mm by 0.5 mm) in a corner of the PCB 308 as shown in image. Deformation of a solder print position for a very small package component in the corner of the PCB 308 can be considered as the worst scenario (solder offset) for this component assembly. To compensate for this offset, an adjustable strain range is applied in accordance with embodiments of the present invention.

The adjustable strain range or limit for the solution covers the PCB specification strain limit (+/−0.034% in the example) and the largest deformation in the worst use case (−0.042% in the example). Therefore, in this example, the strain range/limit applied is −0.042% to +0.034%. In an embodiment, the AI model can automatically analyze and adjust the strain limit by collecting operating data.

Applied stencil stress is provided on stencils and is commonly between 35 N/cm-70 N/cm (or cm²) for metal stencils in the industry. In accordance with the present embodiments, a stencil material is not limited to metal, so the stencil stress can be varied and adjusted, e.g., by the AI model 220. The applied stencil stress can therefor be above or below the industry range.

To obtain a set of stencil printing parameters and conditions that are more compatible with the present embodiment, an initial setting for the applied stencil stress can include a setting to a lowest stencil stress, e.g., 35 N/cm.

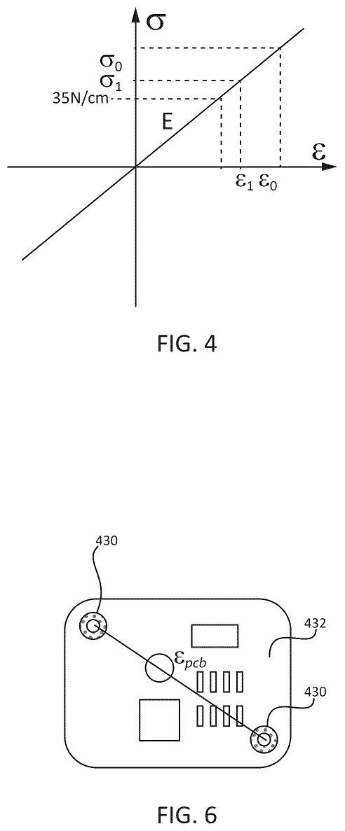

Referring to FIG. 4, a graph of stress (σ) and strain (ε) is shown for an elastic response for a stencil in accordance with the present embodiments. During operation, initial conditions for the printing stencil can include a pre-set stress and strain, with an initial pre-stress value σ₀>0 and initial strain value ε₀>0. After PCB deformation occurs and is detected, the system 200 adjusts the stress to σ₁ to obtain a strain change to ε₁, which provides compensation for the detected PCB deformation.

In an example, E (Modulus of Elasticity) of the stencil material is shown, where E=σ/ε (Tensile stress/Tensile strain). The system 200 can adjust the stencil stress (σ) to obtain a strain change (ε) after the strain range/limit and E-modulus are defined and input to the system 200.

Also, by defining the required range of stencil strain (ε) and the stress range/limit (σ) that the system plans to control, the system determines the requirement of E-modulus that the stencil material needs to be. It should be understood that with the capability for adjustment, materials are not as limited as previously. While metals and/or polymers can be employed for stencils 102, other materials, such as composite materials can be employed. The material response to stress/strain can include non-linearities that can be compensated for using AI technology with AI model 220.

Returning to the example, the range of the stencil strain is −0.042% to +0.034% with the largest strain for the stencil being −0.042%. A target control stress range is set between 35-70 N/cm. An applied maximum Δε=0.042%.

Then, the calculations can include ε₀=70N/cm/E, ε₀−0.042%=35N/cm/E and E=8.3 GPa (which is the E-Modulus close to Polymer and Nylon which are commonly applied in silk-screen printing).

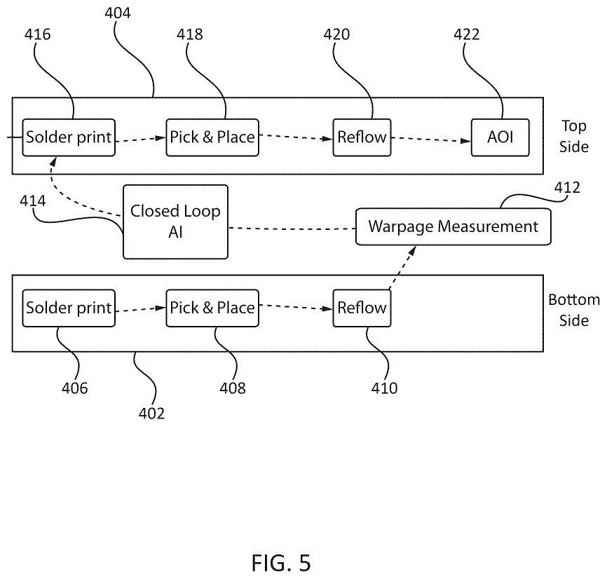

Referring to FIG. 5, a method for adjusting a stencil is shown in accordance with an embodiment. A PCB is to be processed on a bottom side 402 and a top side 404. As such, a solder print process is conducted in block 406 on the bottom side 402 of the PCB. In block 408, a pick and place machine places components on the bottom side 402. A reflow process is provided in block 410 to reflow the solder to make electrical connections between the PCB and the components. The reflow process adds heat to the PCB/stencil system and thermal expansion occurs. After solder printing, pick and place mounting, and reflow soldering, the PCB will be affected with warpage/shrinkage due to the PCB's laminate characteristics. The thermal expansion or warpage due to processing is measured in block 412 by an inspection unit (e.g., AOI).

In block 414, the measurements from block 412 are employed by an AI system to determine compensation strain, and forces that need to be applied to the stencil to provide re-alignment fine-tuning of the stencil relative to the PCB. The AI system can include a closed loop function or closed-loop transfer function system. In a closed loop function, a transfer function defines the mathematical relationship between the input and the output. A change on the output by the input or the relationship between the detected sensor value is known as the gain of the system. The AI model 220 in accordance with embodiments of the present invention is developed for the closed loop function to improve the solder printing performance.

An amount of PCB shrinkage (ε_{pcb}) can be measured by fiducial mark recognition from a solder printing machine, or any dimensional measurement techniques (e.g., CMM, etc.). FIG. 6, shows fiducial markers 430 on a diagonal across a PCB 432 to provide a measure of shrinkage strain (ε_{pcb}). Fiducial mark recognition can provide compensation of the dimensional tolerances of the PCB 432, but fiducial mark recognition has limits and cannot provide a solution for larger PCB shrinkage scenarios, which the present embodiments address.

Once the amount of compensation is determined, the stencil is adjusted in block 414 to compensate for any expansion or warpage in the PCB. This can include adjusting the stress (strain or force) applied in the X and Y directions of the stencil. The adjustment can be checked by the inspection system to ensure alignment.

Now, solder printing a top side 404 of the PCB can be performed with greater accuracy since the dimensional offset between the stencil and the PCB are accounted for. Processing continues with a pick and place machine placing components on the top side 404, in block 418. A reflow process is provided in block 420 to reflow the solder to make electrical connections between the PCB and the components on the top side 404. A dimensional inspection can be conducted in block 422, e.g., by an inspection unit (e.g., AOI).

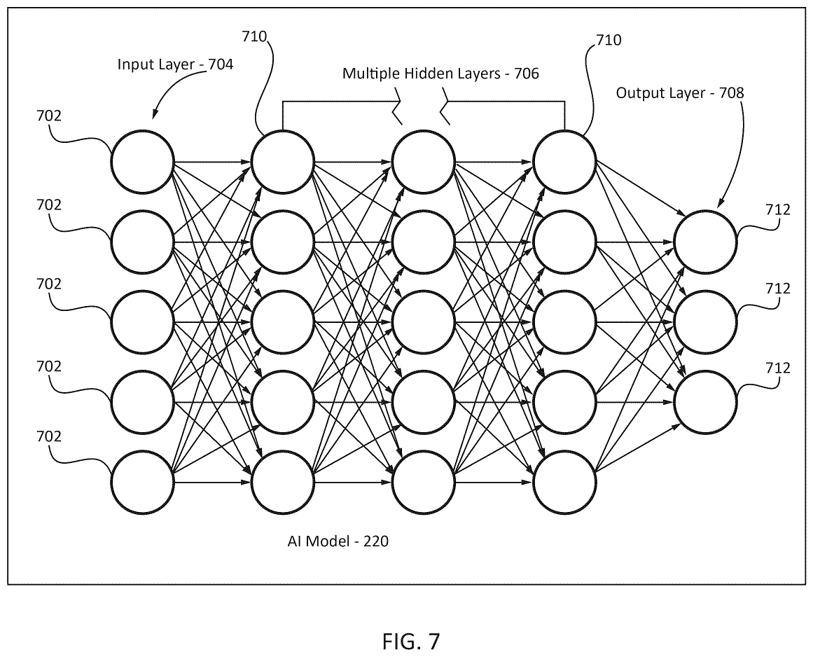

Referring to FIG. 7, a schematic diagram of a neural network is shown for an AI model in accordance with embodiments of the present invention. The AI model 220 can be trained using, e.g., the PCB shrinkage ε_{pcb} data, the solder printing parameter data (printing speed, pressure, cleaning frequency, snapoff distance etc . . . ), the applied stencil stress σ data, and the corresponding quality result data (yield, defective part per million (dppm), etc.). The AI model 220 for printing parameter prediction can employ an AI model formula Y=f(X), where: Y is a printing parameter prediction [printing, speed, pressure, cleaning frequency, snapoff, stencil stress σ]; X is the PCB shrinkage ε_{pcb}, quality yield, defect dppm and f is the AI model function (for example, an Artificial Neural Network (ANN) model). Production and process data can be collected to train the AI model 220 for further inference needs. Once the AI model 220 is trained, the AI model 220 can be used to inference the optimized printing parameter, based on the input of PCB shrinkage ε_{pcb}, expected quality yield, defect dppm, etc.

The AI model 220 may be used to implement parts of the present systems. A neural network is a generalized system that improves its functioning and accuracy through exposure to additional empirical data. The neural network becomes trained by exposure to the empirical data. During training, the neural network stores and adjusts a plurality of weights that are applied to the incoming empirical data. By applying the adjusted weights to the data, the data can be identified as belonging to a particular predefined class from a set of classes or a probability that the input data belongs to each of the classes can be output.

The empirical data, also known as training data, from a set of examples can be formatted as a string of values and fed into the input of the neural network. Each example may be associated with a known result or output. Examples can include solid-state batteries having particular failure modes being associated with countermeasures, shock and vibration response features associated with countermeasures, etc. Each example can be represented as a pair, (x, y), where x represents the input data and y represents the known output. The input data may include a variety of different data types, and may include multiple distinct values. The network can have one input node for each value making up the example's input data, and a separate weight can be applied to each input value. The input data can, for example, be formatted as a vector, an array, or a string depending on the architecture of the neural network being constructed and trained.

The neural network “learns” by comparing the neural network output generated from the input data to the known values of the examples, and adjusting the stored weights to minimize the differences between the output values and the known values. The adjustments may be made to the stored weights through back propagation, where the effect of the weights on the output values may be determined by calculating the mathematical gradient and adjusting the weights in a manner that shifts the output towards a minimum difference. This optimization, referred to as a gradient descent approach, is a non-limiting example of how training may be performed. A subset of examples with known values that were not used for training can be used to test and validate the accuracy of the neural network.

During operation, the trained neural network can be used on new data that was not previously used in training or validation through generalization. The adjusted weights of the neural network can be applied to the new data, where the weights estimate a function developed from the training examples. The parameters of the estimated function which are captured by the weights are based on statistical inference.

In layered neural networks, nodes are arranged in the form of layers. A deep neural network, such as a multilayer perceptron, can have an input layer 704 of source nodes 702, one or more computation layer(s) or hidden layers 706 having one or more computation nodes 710, and an output layer 708, where there is a single output node 712 for each possible category into which the input example could be classified. The input layer 704 can have a number of source nodes 702 equal to the number of data values in the input data. The computation nodes 710 in the computation layer(s) 706 can also be referred to as hidden layers, because they are between the source nodes 702 and output node(s) 712 and are not directly observed. Each node 710 in a computation layer generates a linear combination of weighted values from the values output from the nodes in a previous layer, and applies a non-linear activation function that is differentiable over the range of the linear combination. The weights applied to the value from each previous node can be denoted, for example, by w₁, w₂, . . . wₙ₋₁, wₙ. The output layer 708 provides the overall response of the network to the input data. A deep neural network can be fully connected, where each node 710 in a computational layer 706 is connected to all other nodes in the previous layer, or may have other configurations of connections between layers. If links between nodes are missing, the network is referred to as partially connected.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

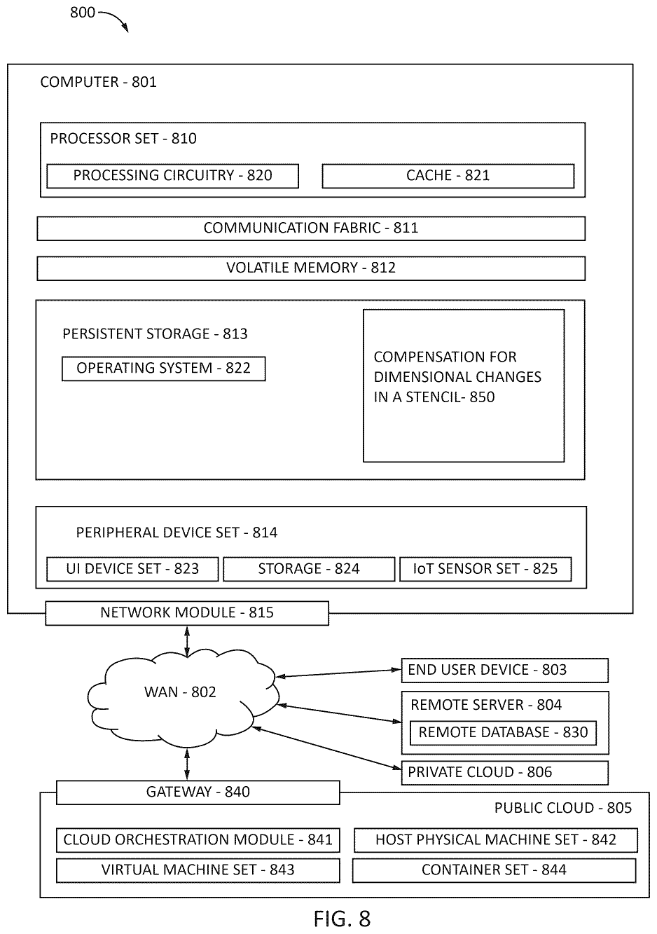

Referring to FIG. 8, a computing environment 800 contains an example of an environment for the execution of at least some of the computer code involved in performing the inventive methods, such as compensation for dimensional changes in a stencil 850. In addition to block 850, computing environment 800 includes, for example, computer 801, wide area network (WAN) 802, end user device (EUD) 803, remote server 804, public cloud 805, and private cloud 806. In this embodiment, computer 801 includes processor set 810 (including processing circuitry 820 and cache 821), communication fabric 811, volatile memory 812, persistent storage 813 (including operating system 822 and block 850, as identified above), peripheral device set 814 (including user interface (UI) device set 823, storage 824, and Internet of Things (IoT) sensor set 825), and network module 815. Remote server 804 includes remote database 830. Public cloud 805 includes gateway 840, cloud orchestration module 841, host physical machine set 842, virtual machine set 843, and container set 844.

COMPUTER 801 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 830. As is well understood in the art of computer technology, and depending upon the technology, performance of a computer-implemented method may be distributed among multiple computers and/or between multiple locations. On the other hand, in this presentation of computing environment 800, detailed discussion is focused on a single computer, specifically computer 801, to keep the presentation as simple as possible. Computer 801 may be located in a cloud, even though it is not shown in a cloud in FIG. 8. On the other hand, computer 801 is not required to be in a cloud except to any extent as may be affirmatively indicated.

PROCESSOR SET 810 includes one, or more, computer processors of any type now known or to be developed in the future. Processing circuitry 820 may be distributed over multiple packages, for example, multiple, coordinated integrated circuit chips. Processing circuitry 820 may implement multiple processor threads and/or multiple processor cores. Cache 821 is memory that is located in the processor chip package(s) and is typically used for data or code that should be available for rapid access by the threads or cores running on processor set 810. Cache memories are typically organized into multiple levels depending upon relative proximity to the processing circuitry. Alternatively, some, or all, of the cache for the processor set may be located “off chip.” In some computing environments, processor set 810 may be designed for working with qubits and performing quantum computing.

Computer readable program instructions are typically loaded onto computer 801 to cause a series of operational steps to be performed by processor set 810 of computer 801 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 821 and the other storage media discussed below. The program instructions, and associated data, are accessed by processor set 810 to control and direct performance of the inventive methods. In computing environment 800, at least some of the instructions for performing the inventive methods may be stored in block 850 in persistent storage 813.

COMMUNICATION FABRIC 811 is the signal conduction path that allows the various components of computer 801 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 812 is any type of volatile memory now known or to be developed in the future. Examples include dynamic type random access memory (RAM) or static type RAM. Typically, volatile memory 812 is characterized by random access, but this is not required unless affirmatively indicated. In computer 801, the volatile memory 812 is located in a single package and is internal to computer 801, but, alternatively or additionally, the volatile memory may be distributed over multiple packages and/or located externally with respect to computer 801.

PERSISTENT STORAGE 813 is any form of non-volatile storage for computers that is now known or to be developed in the future. The non-volatility of this storage means that the stored data is maintained regardless of whether power is being supplied to computer 801 and/or directly to persistent storage 813. Persistent storage 813 may be a read only memory (ROM), but typically at least a portion of the persistent storage allows writing of data, deletion of data and re-writing of data. Some familiar forms of persistent storage include magnetic disks and solid state storage devices. Operating system 822 may take several forms, such as various known proprietary operating systems or open source Portable Operating System Interface-type operating systems that employ a kernel. The code included in block 850 typically includes at least some of the computer code involved in performing the inventive methods.

PERIPHERAL DEVICE SET 814 includes the set of peripheral devices of computer 801. Data communication connections between the peripheral devices and the other components of computer 801 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 823 may include components such as a display screen, speaker, microphone, wearable devices (such as goggles and smart watches), keyboard, mouse, printer, touchpad, game controllers, and haptic devices. Storage 824 is external storage, such as an external hard drive, or insertable storage, such as an SD card. Storage 824 may be persistent and/or volatile. In some embodiments, storage 824 may take the form of a quantum computing storage device for storing data in the form of qubits. In embodiments where computer 801 is required to have a large amount of storage (for example, where computer 801 locally stores and manages a large database) then this storage may be provided by peripheral storage devices designed for storing very large amounts of data, such as a storage area network (SAN) that is shared by multiple, geographically distributed computers. IoT sensor set 825 is made up of sensors that can be used in Internet of Things applications. For example, one sensor may be a thermometer and another sensor may be a motion detector.

NETWORK MODULE 815 is the collection of computer software, hardware, and firmware that allows computer 801 to communicate with other computers through WAN 802. Network module 815 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 815 are performed on the same physical hardware device. In other embodiments (for example, embodiments that utilize software-defined networking (SDN)), the control functions and the forwarding functions of network module 815 are performed on physically separate devices, such that the control functions manage several different network hardware devices. Computer readable program instructions for performing the inventive methods can typically be downloaded to computer 801 from an external computer or external storage device through a network adapter card or network interface included in network module 815. WAN 802 is any wide area network (for example, the internet) capable of communicating computer data over non-local distances by any technology for communicating computer data, now known or to be developed in the future. In some embodiments, the WAN 802 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 803 is any computer system that is used and controlled by an end user (for example, a customer of an enterprise that operates computer 801), and may take any of the forms discussed above in connection with computer 801. EUD 803 typically receives helpful and useful data from the operations of computer 801. For example, in a hypothetical case where computer 801 is designed to provide a recommendation to an end user, this recommendation would typically be communicated from network module 815 of computer 801 through WAN 802 to EUD 803. In this way, EUD 803 can display, or otherwise present, the recommendation to an end user. In some embodiments, EUD 803 may be a client device, such as thin client, heavy client, mainframe computer, desktop computer and so on.

REMOTE SERVER 804 is any computer system that serves at least some data and/or functionality to computer 801. Remote server 804 may be controlled and used by the same entity that operates computer 801. Remote server 804 represents the machine(s) that collect and store helpful and useful data for use by other computers, such as computer 801. For example, in a hypothetical case where computer 801 is designed and programmed to provide a recommendation based on historical data, then this historical data may be provided to computer 801 from remote database 830 of remote server 804.

PUBLIC CLOUD 805 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 805 is performed by the computer hardware and/or software of cloud orchestration module 841. The computing resources provided by public cloud 805 are typically implemented by virtual computing environments that run on various computers making up the computers of host physical machine set 842, which is the universe of physical computers in and/or available to public cloud 805. The virtual computing environments (VCEs) typically take the form of virtual machines from virtual machine set 843 and/or containers from container set 844. It is understood that these VCEs may be stored as images and may be transferred among and between the various physical machine hosts, either as images or after instantiation of the VCE. Cloud orchestration module 841 manages the transfer and storage of images, deploys new instantiations of VCEs and manages active instantiations of VCE deployments. Gateway 840 is the collection of computer software, hardware, and firmware that allows public cloud 805 to communicate through WAN 802. Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 806 is similar to public cloud 805, except that the computing resources are only available for use by a single enterprise. While private cloud 806 is depicted as being in communication with WAN 802, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 805 and private cloud 806 are both part of a larger hybrid cloud.

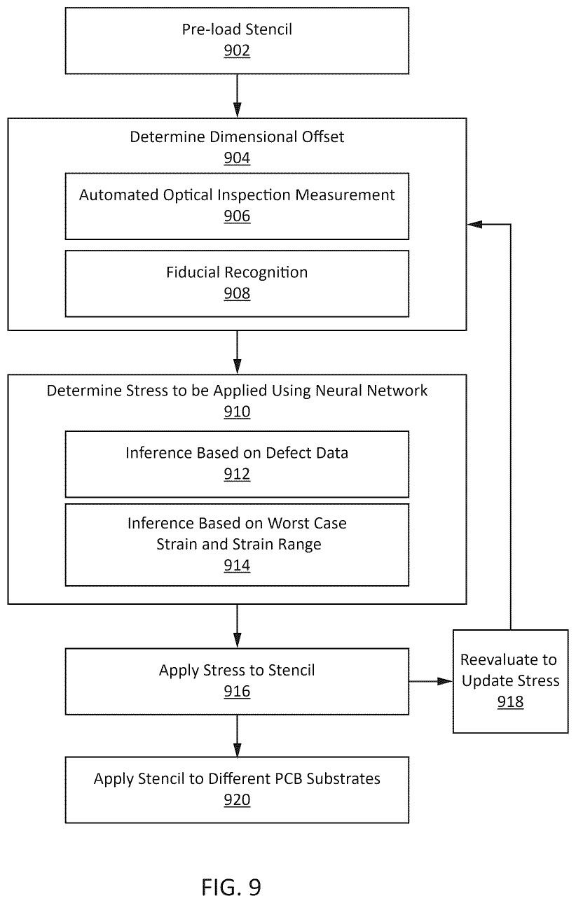

Referring to FIG. 9, systems and methods for adjusting a solder paste stencil are shown in accordance with embodiments of the present invention. In block 902, a solder paste stencil is loaded in a fixture in contact with a PCB. The stencil is preloaded with an initial stress that can include a minimum stress (e.g., 35 N/cm) in an acceptable stress range. Note the present embodiments are not limited to this stress range when adjustments are made. During processing the PCB can be subjected to various processes, which can include one or more reflow processes.

In block 904, processing warpage between the solder paste stencil and the PCB are measured to determine a dimensional offset strain due to the processing warpage due to the various processes. This can be in response to processing warpage measurements between the solder paste stencil and the printed circuit board.

In block 906, measuring can include inspecting dimensional offsets between the solder paste stencil and the printed circuit board using an automated optical inspection tool. In block 908, processing warpage can be measured between the solder paste stencil and the printed circuit board by employing fiducial markers and fiducial marker recognition to estimate strain across the printed circuit board.

In block 910, a stress to be applied to the stencil is determined by accessing a neural network to output the stress to be applied based on the dimensional offset strain. In block 912, the stress to be applied to the stencil can be determined by inferencing the neural network to output an optimized stress parameter based upon historical defect data. In block 914, the stress to be applied to the stencil can be determined by inferencing the neural network with a largest deformation in a worst use case and a strain range to determine the stress to be applied to the stencil.

In block 916, the stress is applied to the stencil to compensate for the warpage. The stress can be applied to the stencil by tensioning a wire mesh supporting the stencil using one or more net haulers. A computer system can generate signals (control signals to e.g., one or more net haulers) to apply the stress to the stencil to compensate for the warpage.

In block 918, dimensional offsets are reevaluated to reapply an updated stress in a closed feedback loop. In block 920, a same stencil for a plurality of different printed circuit board substrates can be employed by adjusting a size of the stencil. The stencil pattern can compensate for different PCB substrate materials having a same stencil pattern. This saves cost on development and fabricating of unique stencils for different substrate materials (e.g., material from different vendors, etc.).

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor-or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), FPGAs, and/or PLAs.

These and other variations of a hardware processor subsystem are also contemplated in accordance with embodiments of the present invention.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method for adjusting a solder paste stencil, comprising:
preloading a solder paste stencil in contact with a printed circuit board;
measuring processing warpage between the solder paste stencil and the printed circuit board to determine a dimensional offset strain due to the processing warpage;
determining a stress to be applied to the solder paste stencil by accessing a neural network to output the stress based on the dimensional offset strain; and
applying the stress to the solder paste stencil to compensate for the processing warpage.

2. The method of claim 1, further comprising reevaluating dimensional offsets to reapply an updated stress in a closed feedback loop.

3. The method of claim 1, wherein measuring processing warpage includes inspecting dimensional offset between the solder paste stencil and the printed circuit board using an automated optical inspection tool.

4. The method of claim 1, wherein measuring processing warpage between the solder paste stencil and the printed circuit board includes employing fiducial markers to estimate strain across the printed circuit board.

5. The method of claim 1, wherein determining the stress to be applied to the solder paste stencil includes inferencing the neural network to output an optimized stress parameter based upon historical defect data.

6. The method of claim 1, wherein determining the stress to be applied to the solder paste stencil includes inferencing the neural network with a largest deformation in a worst use case and a strain range to determine the stress to be applied to the solder paste stencil.

7. The method of claim 1, wherein applying the stress to the solder paste stencil includes tensioning a wire mesh supporting the solder paste stencil using one or more net haulers.

8. The method of claim 1, further comprising using a same stencil for a plurality of different printed circuit board substrates by adjusting a size of the solder paste stencil.

9. A system for adjusting a solder paste stencil, comprising:
a hardware processor; and
a memory that stores a computer program which, when executed by the hardware processor, causes the hardware processor to:
apply a preload to a solder paste stencil in contact with a printed circuit board;
in response to processing warpage measurements between the solder paste stencil and the printed circuit board, determine a dimensional offset strain due to processing warpage;
determine a stress to be applied to the solder paste stencil by accessing a neural network to output the stress based on the dimensional offset strain; and
generate signals to apply the stress to the solder paste stencil to compensate for the processing warpage.

10. The system of claim 9, wherein the computer program causes the hardware processor to reevaluate dimensional offsets to reapply an updated stress in a closed feedback loop.

11. The system of claim 9, wherein the computer program causes the hardware processor to determine the dimensional offset strain due to the processing warpage in accordance with measurements of an automated optical inspection tool.

12. The system of claim 9, wherein the computer program causes the hardware processor to estimate strain across the printed circuit board using fiducial markers.

13. The system of claim 9, wherein the computer program causes the hardware processor to determine the stress to be applied to the solder paste stencil by inferencing the neural network to output an optimized stress parameter based upon historical defect data.

14. The system of claim 9, wherein the computer program causes the hardware processor to determine the stress to be applied to the solder paste stencil by inferencing the neural network with a largest deformation in a worst use case and a strain range to determine the stress to be applied to the solder paste stencil.

15. The system of claim 9, wherein the computer program causes the hardware processor to apply the stress to the solder paste stencil by tensioning a wire mesh supporting the solder paste stencil using one or more net haulers.

16. The system of claim 9, wherein a same stencil is employed for a plurality of different printed circuit board substrates by adjusting a size of the solder paste stencil.

17. A computer program product for adjusting a solder paste stencil, the computer program product comprising a computer readable storage medium having program instructions embodied therewith, the program instructions executable by a hardware processor to cause the hardware processor to:
apply a preload to a solder paste stencil in contact with a printed circuit board;
in response to processing warpage measurements between the solder paste stencil and the printed circuit board, determine a dimensional offset strain due to processing warpage;
determine a stress to be applied to the solder paste stencil by accessing a neural network to output the stress based on the dimensional offset strain; and
generate signals to apply the stress to the solder paste stencil to compensate for the processing warpage.

18. The computer program product of claim 17, wherein the program instructions cause the hardware processor to reevaluate dimensional offsets to reapply an updated stress in a closed feedback loop.

19. The computer program product of claim 17, wherein the computer program product causes the hardware processor to determine the stress to be applied to the solder paste stencil by inferencing the neural network to output an optimized stress parameter based upon historical defect data.

20. The computer program product of claim 17, wherein the computer program product causes the hardware processor to determine the stress to be applied to the solder paste stencil by inferencing the neural network with a largest deformation in a worst use case and a strain range to determine the stress to be applied to the solder paste stencil.
